(19) United States
(12) Patent Application Publication
(10) Pub. No.: US 2024/0074337 A1
(43) Pub. Date: Feb. 29, 2024

(54) MEMORY DEVICE AND METHOD OF MAKING THE SAME

(71) Applicant: Taiwan Semiconductor Manufacturing Company, Ltd., Hsinchu (TW)

(72) Inventors: Hengyuan Lee, Hsinchu County (TW); Cheng-Chun Chang, Taoyuan City (TW); Chen-Feng Hsu, Hsinchu (TW); Tung-Ying Lee, Hsinchu City (TW); Xinyu BAO, Fremont, CA (US)

(73) Assignee: Taiwan Semiconductor Manufacturing Company, Ltd., Hsinchu (TW)

(21) Appl. No.: 17/896,081

(22) Filed: Aug. 26, 2022

(51) Int. Cl. H01L 45/00; H01L 27/24

(52) U.S. Cl. CPC H01L 45/144; H01L 27/2409; H01L 45/06; H01L 45/1625

(57) ABSTRACT

A memory device includes a substrate, a bottom electrode disposed over the substrate, a top electrode disposed over the bottom electrode, and a phase change layer disposed between the top electrode and bottom electrode. The phase change layer includes a GeSbTe material that contains a Ge content of about 20 at % or less, a Sb content of about 30 at % or more, and a Te content of about 40 at % at or more.

### BACKGROUND

Memory devices are used in integrated circuits for electronic applications, including radios, televisions, cell phones, and personal computing devices, as examples. A phase-change random-access memory (PCRAM) is a form of non-volatile random-access computer memory. PCRAM technology is based upon a material that can be either amorphous or crystalline at normal ambient temperatures. When the material is in the amorphous state, the material has a high electrical resistance. When the material is in the crystalline state, the material has a low electrical resistance. PCRAM devices have several operating and engineering advantages, including high speed, low power, non-volatility, high density, and low cost. While the existing PCRAM devices have generally been adequate for their intended purposes, as device scaling-down continues, they have not been entirely satisfactory in all respects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a PCRAM structure including a phase-change memory cell and a field effect transistor, according to some embodiments of the present disclosure.

FIG. 2 is a schematic view of a PCRAM structure including multiple phase-change memory cells, according to some embodiments of the present disclosure.

FIG. 3 is a cross-sectional view of a memory device according to some embodiments of the present disclosure.

FIG. 4A to FIG. 4B are cross-sectional views of phase-change memory cells that may be included in the memory device of FIG. 3, according to some embodiments of the present disclosure.

FIG. 5 is a ternary composition diagram of phase change materials according to some embodiments of the disclosure.

FIG. 6 illustrates a co-sputtering apparatus for forming a phase change layer according to some embodiments of the present disclosure.

FIG. 7 is a flow chart showing a method of forming a memory device according to some embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Ranges can be expressed herein as from “about” one particular value, and/or to “about” another particular value. When such a range is expressed, examples include from the one particular value and/or to the other particular value. Similarly, when values are expressed as approximations, by use of the antecedent “about” or “substantially” it will be understood that the particular value forms another aspect. In some embodiments, a value of “about X” may include values of +/−1% X. It will be further understood that the endpoints of each of the ranges are significant both in relation to the other endpoint, and independently of the other endpoint.

A phase-change random-access memory (PCRAM) is a non-volatile memory device that makes use of different resistive phases and heat induced phase transition between the phases of phase-change materials including chalcogenide and resistive materials. A PCRAM may be composed of many memory cells that operate independently. A PCRAM cell may include a heater and a resistor. The PCRAM cell may operate as a data storage element made mainly of a reversible phase-change material to provide at least two dramatically different resistivities for logical “0” state and “1” state. To read a state (data) from the PCRAM cell, a sufficiently small current is applied to the phase-change material without triggering the heater to generate heat. In this way, the resistivity of the phase-change material may be measured and the states representing the resistivities, i.e. a “0” state for high resistivity or a “1” state for low resistivity can be read.

To write a state (data) in the PCRAM cell, for example, to write a “1” state representing a low resistivity phase of the phase-change material, a medium electric current may be applied to the heater which generates heat for annealing the phase-change material at a temperature above the crystallization temperature but below the melting temperature of the phase-change material for a time period to achieve a crystalline phase. As the phase-change material heats to a temperature above the crystallization temperature, the material may enter a crystalline state where the phase-change material exhibits a low electrical resistance. With the low resistance value, a charge may flow into the material to establish the “1” state value.

To write a “0” state representing a high resistivity phase of the phase-change material, a very large electric current may be applied to the heater to generate heat to melt the phase-change material at a temperature higher than the melting temperature of the phase-change material; and the electric current is abruptly cut off to lower the temperature to below the crystallization temperature of the phase-change material to quench and stabilize the amorphous structure of phase-change material. As the phase change material enters the amorphous state, the phase-change material exhibits a high resistance value. The high resistance value may impede a charge from flowing into the material to establish a “0” state value. The very large electric current can thus be in a pulse form.

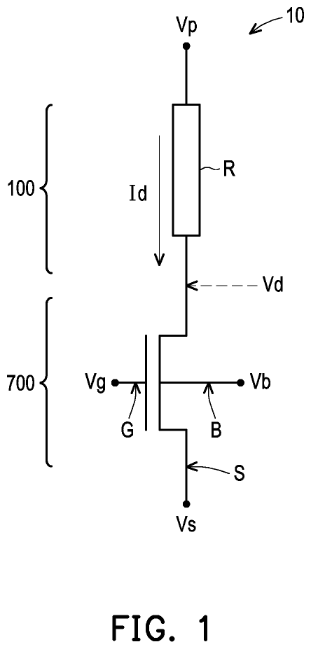

FIG. 1 is a schematic view of a PCRAM structure 10 constructed according to an embodiment. The PCRAM structure 10 may include a phase-change memory cell 100 and a current-controlling device 700 electrically connected to each other. The phase-change memory cell 100 includes a phase-change material layer interposed between two electrodes. In some embodiments, the resistance of the phase change layer material is configured to be adjusted into multiple levels that represent different logic states, respectively.

The current-controlling device 700 in the PCRAM structure 10 may be a device that is operable to control the current flow through the phase-change memory cell 100 during the operations. In the present embodiment, the current-controlling device 700 is a transistor (or selector transistor), such as a field effect transistor (FET). For example, the FET 700 may be a metal-oxide-semiconductor (MOS) FET. The FET 700 includes source S, drain D and gate G. In some embodiments, the source S and drain D may be designed asymmetrically, such that a voltage drop over the FET during a forming operation and an off-state leakage current may be collectively optimized. The source S and drain D may separately formed, so that the source S and drain D may be independently tuned to achieve the asymmetric structure. More particularly, the source S and drain D may be different from each other in term of doping concentration. In some embodiments, the source and drain may be different in at least one of doping concentration, doping profile and doping species. In other embodiments, the source S and drain D may be designed symmetrically and simultaneously formed, and the operation may be properly adjusted by applying different voltages to generate a voltage drop over the FET.

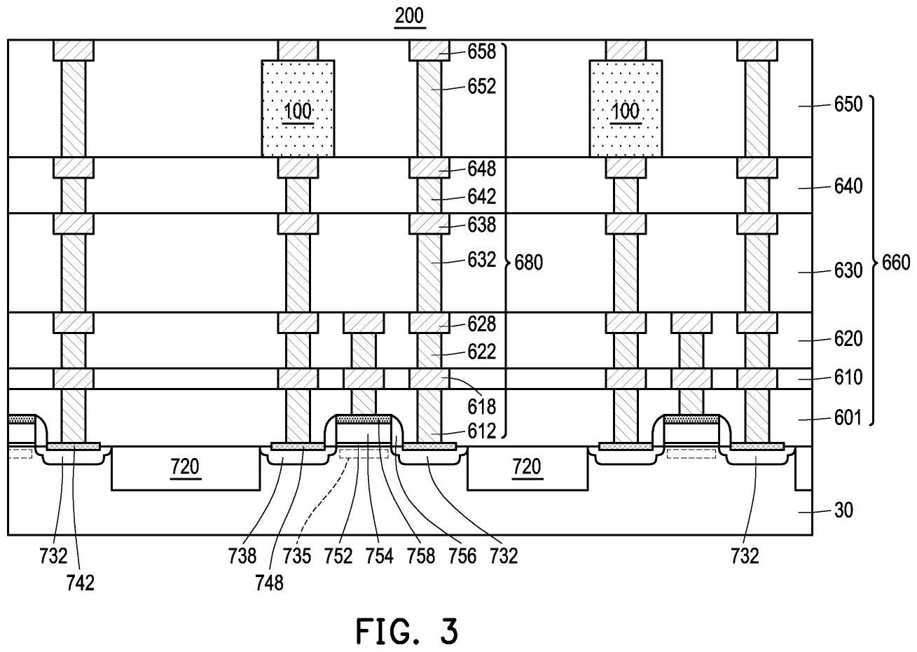

The FET 700 may be electrically coupled with the memory cell 100. In the present example, one electrode of the memory cell 100 is electrically connected to the drain D of the FET 700. The gate G of the FET 700 may be electrically connected to a word line, and another electrode of the memory cell 100 may be electrically connected to a bit line, as discussed in detail with reference to FIG. 3.

As illustrated in FIG. 1, the gate, source, drain and body of the FET 700 are labeled as G, S, D, and B, respectively. The corresponding voltages of the gate, source, drain and substrate during the operations are labeled as Vg, Vs, Vd and Vb, respectively. Furthermore, during operation, the current through the memory cell 100 is labeled as Id, and the voltage applied to one electrode of memory cell 100 from the bit line is labeled as Vp.

In one embodiment, the PCRAM structure 10 may be a two terminal memory structure, with the gate of the FET 700 operating as a first terminal, and one electrode of the memory cell 100 operating as a second terminal. The first terminal is controlled by a first voltage applied to the gate G of FET 700 from the word line, and the second terminal is controlled by a second voltage applied to the one electrode of the phase-change memory cell from the bit line. In one example, the source is grounded, and the body of the FET 700 is grounded or floating.

In another embodiment, the PCRAM structure 10 may be a three terminal memory structure, wherein the three terminals include the gate of FET 700 as a first terminal, the electrode of the memory cell 100 (the electrode that is not directly connected with the drain of the transistor) as a second terminal, and the source of the FET 700 as a third terminal. Particularly, during the operations of the phase-change memory cell 100, the first terminal (gate) may be controlled by a first voltage from the word line, the second terminal may be controlled by a second voltage from the bit line, and the third terminal may be controlled by a third voltage from a source line. In one example, the source is grounded. In an alternative example, the second terminal is grounded. The substrate (or the body) of the FET 700 may be grounded or floating.

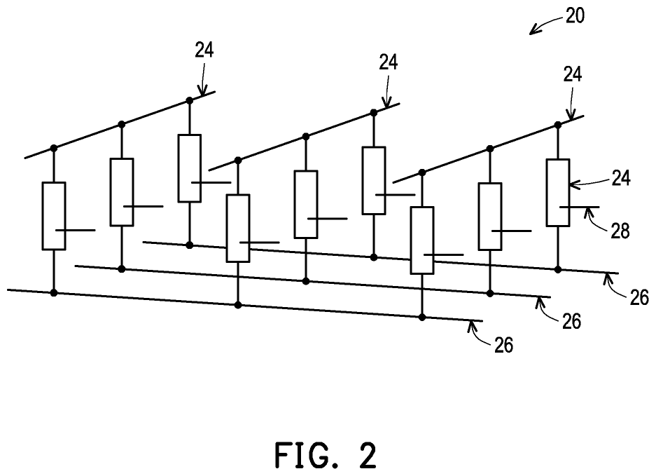

FIG. 2 is a schematic view of a memory structure 20 having a plurality of phase-change memory cells 100 constructed according some embodiments of the present disclosure. The phase-change memory cells 100 may be configured in an array coupled with a plurality of word lines 24 and a plurality of bit lines 26. In some embodiments, the word lines 24 and the bit lines 26 may be cross-configured. Furthermore, each of the phase-change memory cells 100 may be operable to achieve multiple resistance levels and accordingly multiple bit storage. In the present embodiment, source lines 28 are configured to connect to the sources of the memory cells 100, respectively. The source lines 28 may be configured such that one source line 28 is coupled with one respective phase-change memory cell 100. Alternatively, one source line may be coupled with a subset of the phase-change memory cells 100 in the memory structure 20.

FIG. 3 is a cross sectional view of a memory device 200, according to some embodiments of the present disclosure. Referring to FIG. 3, the memory device 200 includes one or more phase-change memory cells 100 and corresponding field effect transistors (FETs) 700, disposed on a substrate 30. The memory device 200 can include a two-dimensional array of memory cells arranged in a 1T1R configuration, i.e., a configuration in which one access transistor is connected to one resistive memory cell.

The substrate 30 can be a semiconductor substrate such as a silicon substrate. Alternatively, or additionally, the substrate 30 may include elementary semiconductor materials, compound semiconductor materials, and/or alloy semiconductor materials. Examples of the elementary semiconductor materials may be, but are not limited to, crystal silicon, polycrystalline silicon, amorphous silicon, germanium, and/or diamond. Examples of the compound semiconductor materials may be, but are not limited to, silicon carbide, gallium arsenic, gallium phosphide, indium phosphide, indium arsenide, and/or indium antimonide. Examples of the alloy semiconductor materials may be, but are not limited to, SiGe, GaAsP, AlInAs, AlGaAs, GaInAs, GaInP, and/or GaInAsP. Other suitable materials within the contemplated scope of disclosure may also be used.

The FETs 700 may provide functions that are needed to operate the memory cells 100. Specifically, the FETs 700 can be configured to control the programming operation, the erase operation, and the sensing (read) operation of the memory cells 100. In some embodiments, the memory device 200 may include sensing circuitry and/or a top electrode bias circuitry on the substrate 30. The FETs 700 may include complementary metal-oxide-semiconductor (CMOS) transistors. The substrate 30 may optionally include additional semiconductor devices, such as resistors, diodes, capacitors, etc.

Shallow trench isolation structures 720 including a dielectric material such as silicon oxide can be formed in an upper portion of the substrate 30. Suitable doped semiconductor wells, such as p-type wells and n-type wells can be formed within each area that is laterally enclosed by a continuous portion of the shallow trench isolation structures 720. Accordingly, the FETs 700 may be formed on the substrate 30 between the isolation structures 720, such that the FETs 700 may be electrically isolated from one another by the isolation structures 720.

Each FET 700 may include a source region 732, a drain region 738, a semiconductor channel 735 that includes a surface portion of the substrate 30 extending between the source region 732 and the drain region 738, and a gate structure 750. Each gate structure 750 can include a gate dielectric 752, a gate electrode 754, a gate cap dielectric 758, and a dielectric gate spacer 756. A source-side metal-semiconductor alloy region 742 can be formed on each source region 732, and a drain-side metal-semiconductor alloy region 748 can be formed on each drain region 738.

In some embodiments, the channel region 735 may be doped with a first type dopant, and the source region 732 and the drain region 738 may be doped with a second type dopant, opposite to the first type. In the present example, the FET 700 may be an n-type FET (nFET). Accordingly, the channel region 735 may be p-type channel.

In one embodiment, the source region 732 may be formed by a first ion implantation process, and the drain region 738 may be formed by a second ion implantation process. The second ion implantation process may be different from the first ion implantation process in at least one of doping dose, implanting angle and dopant (doping species). In some embodiments, the first ion implantation process includes forming a first patterned mask on the substrate, and applying the first ion implantation to the substrate using the first patterned mask as an implantation mask. The first patterned mask may include an opening such that a substrate region for the source is uncovered thereby. The first patterned mask may be a patterned photoresist layer formed by a lithography process, or alternatively, a patterned hard mask formed by lithography process and etching. Similarly, the second ion implantation process may include forming a second patterned mask on the substrate, and applying the second ion implantation to the substrate using the second patterned mask as an implantation mask. The second patterned mask may include an opening such that a substrate region for the drain is uncovered thereby. The second patterned mask may be similar to the first patterned mask in terms of formation and composition.

In some embodiments, a device interconnect structure including metal interconnect features 680 embedded by dielectric layers 660 is formed over a device layer, and multiple memory cells such as phase-change memory cells 100 are formed between the lower interconnect structure and the upper interconnect structure of the device interconnect structure.

The metal interconnect features 680 formed in dielectric layers 660 may be formed over the substrate 30 and the devices formed thereon (such as the FETs 700). The dielectric layers 660 can include, for example, a contact-level dielectric layer 601, a first metal-line-level dielectric layer 610, a second line-and-via-level dielectric layer 620, a third line-and-via-level dielectric layer 630, a fourth line-and-via-level dielectric layer 640, and a fifth line-and-via-level dielectric layer 650.

In some embodiments, the method of forming metal interconnect features 680 includes performing single-damascene processes, dual-damascene processes, electroplating process or the like. In some embodiments, the method of forming the dielectric layers 660 includes performing deposition processes followed by photolithography and etching processes.

The metal interconnect features 680 may include metal contacts 612 formed in the contact-level dielectric layer 601 and that contact respective component of the FETs 700, first metal lines 618 formed in the first metal-line-level dielectric layer 610, first metal vias 622 formed in a lower portion of the second line-and-via-level dielectric layer 620, second metal lines 628 formed in an upper portion of the second line-and-via-level dielectric layer 620, second metal vias 632 formed in a lower portion of the third line-and-via-level dielectric layer 630, third metal lines 638 formed in an upper portion of the third line-and-via-level dielectric layer 630, third metal vias 642 formed in a lower portion of the fourth line-and-via-level dielectric layer 640, fourth metal lines 648 formed in an upper portion of the fourth line-and-via-level dielectric layer 640, fourth metal vias 652 formed in a lower portion of the fifth line-and-via-level dielectric layer 650, and fifth metal lines 658 formed in an upper portion of the fifth line-and-via-level dielectric layer 650. In some embodiments, the metal interconnect features 680 can include source line that are connected a source-side power supply for an array of memory elements. The voltage provided by the source lines can be applied to the bottom electrodes through the access transistors provided in the memory array region 100.

Each of the dielectric layers (601, 610, 620, 630, 640, 650) may include a dielectric material such as undoped silicate glass, a doped silicate glass, organosilicate glass, amorphous fluorinated carbon, porous variants thereof, or a combination thereof. Each of the metal interconnect features (612, 618, 622, 628, 632, 638, 642, 648, 658) may include at least one conductive material, which can be a combination of a metal liner layer (such as a metal nitride or a metal carbide) and a metal fill material. Each metal liner layer can include TiN, TaN, WN, TiC, TaC, WC, or a combination thereof, and each metal fill material portion can include W, Cu, Al, Co, Ru, Mo, Ta, Ti, an alloy thereof, or a combination thereof. Other suitable materials within the contemplated scope of disclosure may also be used. In some embodiments, the metal contacts 612 and the first metal lines 618 may be formed as integrated line and contact structure by a dual damascene process, the first metal vias 622 and the second metal lines 628 may be formed as integrated line and via structure by a dual damascene process, the second metal vias 632 and the third metal lines 638 may be formed as integrated line and via structure by a dual damascene process, the third metal vias 642 and the fourth metal lines 648 may be formed as integrated line and via structure by a dual damascene process, and/or the fourth metal vias 652 and the fourth metal lines 648 may be formed as integrated line and via structure by a dual damascene process.

In some embodiments, the memory cells 100 may be disposed within the fifth dielectric layer 650, and each memory cell 100 may be electrically connected to a respective fourth metal line 648 and a fifth metal line 658. However, the present disclosure is not limited to any particular location for the memory cells 100. For example, the memory cells 100 may be disposed within any of the dielectric layers 660.

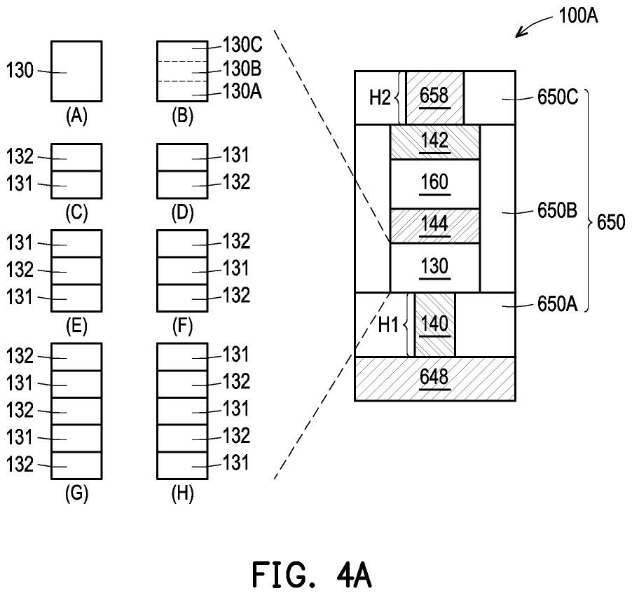

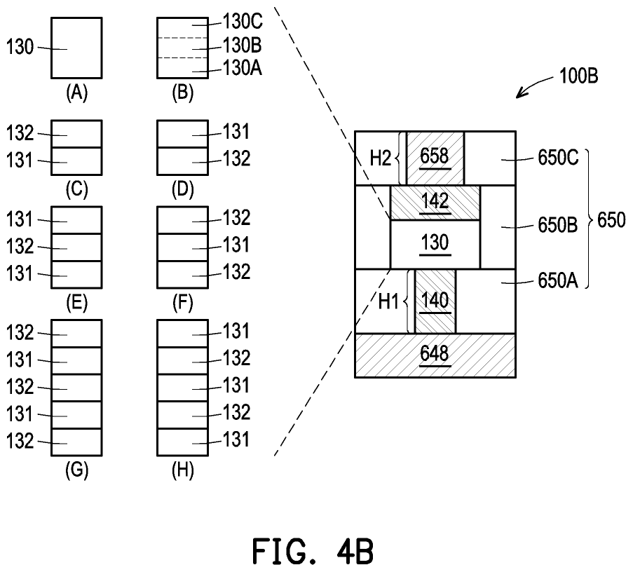

The metal interconnect features 680 may be configured to connect each memory cell 100 to a corresponding FET 700, and to connect the FET 700 to corresponding signal lines. For example, the drain region 738 of the FET 700 may be electrically connected to a bottom electrode (see FIGS. 4A-4B) of the memory cell 100 via, for example, a subset of the metal contacts or vias (612, 622, 632, 642) and a subset of the metal lines (618, 628, 638, 648). Each drain region 738 may be connected to a first node (such as a bottom node) of a respective memory cell 100 via a respective subset of the metal interconnect features 680. The gate electrode 754 of each FET 700 may be electrically connected to a word line, which can be embodied as a subset of the metal interconnect features 680. A top electrode (see FIGS. 4A-4B) of each memory cell 100 may be electrically connected to a respective bit line, which is embodied as a respective subset of the metal interconnect features. Each source region 732 may be electrically connected to a respective source line, which is embodied as a respective subset of the metal interconnect features. While only five levels of metal lines are illustrated in FIG. 3, it is understood that more metal line levels can be formed above the illustrated levels of FIG. 3. Further, it is understood that the levels in which the source lines, word lines, and bit lines are formed may be selected based on design parameters.

FIG. 4A is cross-sectional sectional view of a phase-change memory cell 100A that may be included in the PCRAM device 200 of FIG. 3, according to some embodiments of the present disclosure. Referring to FIGS. 3 and 4A, the memory cell 100A may be disposed between two overlapping conductive lines, such as metal lines 648 and 658. With respect to the memory cell 100A, the metal lines 648, 658 may be respectively referred to herein as a bottom conductive line 648 and a top conductive line 658.

In some embodiments, the memory cell 100A may include a bottom electrode 140 disposed on the bottom conductive line 648, a memory layer such as a phase change layer 130 disposed on the bottom electrode 140, a barrier electrode 144 disposed on the phase change layer 130, a selector layer 160 disposed on barrier electrode 144, and a top electrode 142 disposed on the selector layer 160. The bottom electrode 140 may be electrically connected to the conductive line 648, and the top electrode may be electrically connected to the overlapping conductive line 658.

In some embodiments, the dielectric layer 650 may include a bottom dielectric layer 650A, a middle dielectric layer 650B, and a top dielectric layer 650C. The dielectric layers 650A-650C may have a thickness in a range from about 5 to about 350 nm, for example, although greater or lesser thicknesses may be within the contemplated scope of disclosure.

In some embodiments, the bottom dielectric layer 650A contacts side surfaces of the bottom electrode 140 and top surface of the bottom conductive line 648. In particular, the bottom electrode 140 may be disposed in a via opening or through-hole H1 formed in the bottom dielectric layer 650A and may electrically connect the conductive line 648 and the phase change layer 130. The phase change layer 130, barrier electrode 144, selector layer 160, and the top electrode 142 may be disposed within the middle dielectric layer 650B. For example, the middle dielectric layer 650B may be deposited after forming the top electrode 142. The top dielectric layer 650C may include a through-hole H2 in which the top conductive line 658 is disposed. While the dielectric layers 650A, 650B, 650C are shown in FIG. 4A as being distinct layers, the dielectric layers 650A, 650B, 650C may be substantially indistinguishable from one another.

The electrodes 140, 142, 144 may be formed of a conductive material such as TiN, TaN, TiAlN, the like or a combination thereof. Other suitable materials are within the contemplated scope of disclosure. The electrodes 140, 142, 144 may be configured to provide electrical connection and/or prevent the diffusion metal species from the bottom and/or top metal lines 648, 658 into the phase change layer 130 and/or the selector layer 160. The electrodes 140, 142, 144 may have a thickness in a range from about 5 to about 50 nm. Although greater or lesser thicknesses may be within the contemplated scope of disclosure. One or more of the electrodes 140, 142, 144 may be configured to provide Joule heating to the phase change layer 130. For example, at least the bottom electrodes 140 may be configured to heat the phase change layer 130. The electrodes 140, 142, 144 may also function as a heat sink during quenching (during abrupt cutoff of the current applied to the electrodes 140, 142, 144 to “freeze” the phase change layer 130 in an amorphous phase). The dielectric layer 650 may also be configured to prevent and/or reduce heat transfer between adjacent memory cells 100, so as to avoid thermal disturbance which may disable state retention or interrupt the read/write process.

In some embodiments, the selector layer 160 provides a current-voltage non-linearity to the PCRAM structure, and this reduces leakage current. The selector layer 160 may have a single-layer or multi-layered structure, in some embodiments. The selector layer 160 may have a thickness ranging from about 0.5 nm to about 50 nm. Although greater or lesser thicknesses may be within the contemplated scope of disclosure. In some embodiments, the selector layer 160 is formed by chemical vapor deposition (CVD), pulsed laser deposition (PLD), sputtering, atomic layer deposition (ALD), or any other thin film deposition method.

In some embodiments, the selector layer 160 includes SiOₓ, TiOₓ, AlOₓ, WOₓ, TiₓNO_{z}, HfOₓ, TaOₓ, NbOₓ, the like, or a combination thereof, where x, y and z are non-stoichiometric values. Other suitable materials are within the contemplated scope of disclosure. In some embodiments, the selector layer 160 may be a solid-electrolyte material containing chalcogenide (e.g., one or more of Ge, Sb, S, Te) and optional dopant (e.g., one or more of N, P, S, Si, C). For example, the selector layer 160 includes N, P, S, Si, and/or Te doped AsGeSe, e.g., AsGeSe(N, P, S, Si, Te); N, P, S, Si, and/or Te doped AsGeSeSi, e.g., AsGeSeSi(N, P, S, Si, Te); or the like. For example, the selector layer 160 includes GeCTe, CTe, GeSe, BCTe, SiGeCTe, SiCTe, NGeCTe, NSiGeCTe, NSiCTe, NSeGeCTe, NSiSeCTe, NSeCTe, NBCTe, NSiBCTe, NGeBCTe, the like, or a combination thereof. Other suitable materials are within the contemplated scope of disclosure.

In some embodiments, the phase change layer 130 is disposed between the top electrode 142 and bottom electrode 140, and the phase change layer includes a GeSbTe (hereinafter GST) composition that contains a Ge content of about 20 at % or less, a Sb content of about 30 at % or more, and a Te content of about 40 at % at or more. The specific ranges of the Ge, Sb and Te contents of the composition of the disclosure provide higher crystallization temperature and lower reset current, so as to improve the performance of the device.

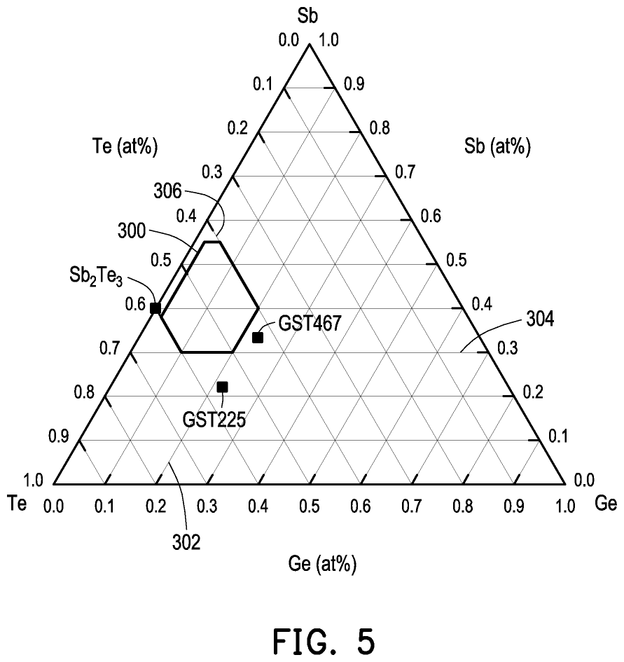

FIG. 5 is a ternary composition diagram of phase change materials according to some embodiments of the disclosure. The compositions of the materials of the disclosure may be read by following the oblique lines 302 to determine the amount (atomic percent) of Ge, following the horizontal lines 304 to determine the amount (atomic percent) of Sb, and following the oblique lines 306 to determine the amount (atomic percent) of Te. In some embodiments, materials of the disclosure encompassed by the shape 300 includes the group of GeₓSb_{y}Te_{z} materials, wherein x, y and z are greater than zero. Specifically, in the materials of the disclosure encompassed by the shape 300, the Ge atomic percentage concentration is within a range from about 1 at % to 20 at %, the Sb atomic percent concentration is within a range from about 30 at % to 55 at %, and the Te atomic percent concentration is within a range from about 40% to 60%. In some embodiments, the GST material of the disclosure has a Ge content of about 5-18 at % such as about 10-15 at %, a Sb content of about 35-50 at % such as about 40-45 at %, and a Te content of about 45-58 at % such as about 50-55 at %. Other values of atomic percent concentrations of Ge, Sb and Te within the contemplated scope of disclosure may also be used.

In some embodiments, the Ge content of the material of the disclosure is less than the Ge content of Ge₄Sb₆Te₇ (hereinafter GST467), but the Sb and Te contents of the material of the disclosure are higher than the Sb and Te contents of GST467. In some embodiments, the materials of the disclosure are referred to as Ge-poor GST467 family materials.

According to various embodiments, the phase change material of the disclosure may be doped with less than about 10 at % of N, Si, Sc, Ga, C, O, N or a combination thereof. For example, the phase change material of the disclosure may be doped with Si, C, O and N to improve its performance. In some embodiments, material of the disclosure may include a Ge-poor GST467 material doped with about 1-10 at % to of the dopant including Si, C, O, N or a combination thereof.

In some embodiments, the crystallization temperature of the Ge-poor GST467 family material of the disclosure is at least 30° C. higher than the crystallization temperatures of the conventional Ge₂Sb₂Te₅ (hereinafter GST225). For example, the Ge-poor GST467 family material of the disclosure has a crystallization temperature of about 170° C. or higher, such as 180° C. or higher, 190° C. or higher, or 200° C. or higher. The higher crystallization temperature of the Ge-poor GST467 family indicates higher stability of amorphous state of Ge-poor GST467 family compared to the conventional GST225. In addition, the materials described in the disclosure are operable with low reset currents, which can be about 30-55% lower than that typical materials of GST225. For example, the reset current of the conventional GST225 is about 1 mA, while the reset current of the Ge-poor GST467 family ranges from about 500 uA to 700 uA.

In some embodiment, the atom percentage concentration of at least one of Ge, Sb and Te of the phase change layer 130 is substantially constant. For example, all the of Ge, Sb and Te atoms are substantially distributed across the phase change layer 130, as shown in the enlarged region (A) of FIG. 4A. However, the disclosure is not limited thereto.

In other embodiments, the atom percentage concentration of at least one of Ge, Sb and Te of the phase change layer 130 is varied (e.g., gradually increased or gradually decreased) in a thickness direction from the bottom electrode 140 to the barrier electrode 144 or the top electrode 142. For example, the atom percentage concentration of Ge of the phase change layer 130 is gradually increased or gradually decreased in a thickness direction from the bottom electrode 140 to the barrier electrode 144. For example, the phase change layer 130 has multiple sublayers 130A, 130B and 130C, and the Ge content of the sublayers 130A, 130B and 130C is gradually decreased from the bottom electrode 140 to the barrier electrode 144, while the Sb and Te contents of the sublayers 130A, 130B and 130C are gradually increased in a thickness direction from the bottom electrode 140 to the barrier electrode 144. For example, the phase change layer 130 has multiple sublayers 130A, 130B and 130C, and the Ge content of the sublayers 130A, 130B and 130C is gradually increased in a thickness direction form the bottom electrode 140 to the barrier electrode 144, while the Sb and Te contents of the sublayers 130A, 130B and 130C are gradually decreased in a thickness direction from the bottom electrode 140 to the barrier electrode 144. Such gradient atom concentration of the sublayers 130A, 130B and 130C is shown in the enlarged view (B) of FIG. 4A. In some embodiments, the lower sublayer 130A may include 0-6 at % Ge, the middle sublayer 130B may include 7-13 at % of Ge, and the upper sublayer 130C may include 14-20 at %. In some embodiments, the lower sublayer 130A may include 14-20 at %, the middle sublayer 130B may include 7-13 at % of Ge, and the upper sublayer 130C may include 0-6 at % Ge. The interface between two adjacent sublayers of the sublayers 130A, 130B and 130C is substantially invisible. The number of the gradient sublayers is not limited to the present disclosure.

In some embodiments, the phase change layer 130 includes first and second sublayers 131 and 132 with a visible interface therebetween, as shown in the enlarged views (C) and (D) of FIG. 4A. For example, the first and second sublayers 131 and 132 are made by different materials. In some embodiments, each of the first and second sublayers 131 and 132 includes Sb₂Te₃, Ge₄Sb₆Te₇ or a combination thereof.

In some embodiments, the phase change layer 130 includes first sublayers 131 and second sublayers 132 alternately stacked, as shown in the enlarged views (E) to (H) of FIG. 4A. For example, the first and second sublayers 131 and 132 are made by different materials. In some embodiments, each of the first and second sublayers 131 and 132 includes Sb₂Te₃, Ge₄Sb₆Te₇ or a combination thereof.

In some embodiments, each first sublayer 131 includes Se₄Sb₆Te₇ and Sb₂Te₃, and each second sublayer 132 includes Se₄Sb₆Te₇. In some embodiments, each first sublayer 131 includes Se₄Sb₆Te₇, and each second sublayer 132 includes Se₄Sb₆Te₇ and Sb₂Te₃.

In some embodiments, each first sublayer 131 includes Se₄Sb₆Te₇ and Sb₂Te₃, and each second sublayer 132 includes Sb₂Te₃. In some embodiments, each first sublayer 131 includes Sb₂Te₃, and each second sublayer 132 includes Se₄Sb₆Te₇ and Sb₂Te₃.

In some embodiments, each first sublayer 131 includes Se₄Sb₆Te₇, and each second sublayer 132 includes Sb₂Te₃. In some embodiments, each first sublayer 131 includes Sb₂Te₃, and each second sublayer 132 includes Se₄Sb₆Te₇.

In some embodiments, as shown in the enlarged views (E) to (H) of FIG. 4A, the Ge contents of the phase change layer 130 may be discontinuously varied in a thickness direction extending between the bottom electrode 140 and the barrier electrode 144 or the top electrode 142. For example, the Ge contents of the first sublayers 131 of the phase change layer 130 are discontinuously changed towards the thickness direction. For example, the Ge contents of the second sublayers 132 of the phase change layer 130 are discontinuously changed towards the thickness direction. However, the disclosure is not limited thereto. In some embodiments, the Ge contents of the first sublayers 131 of the phase change layer 130 are substantially the same. In some embodiments, the Ge contents of the second sublayers 132 of the phase change layer 130 are substantially the same.

In some embodiments, the phase change layer 130 includes Ge₄Sb₆Te₇ and Sb₂Te₃ in a ratio of 10:1 to 1:10, such as 9:1, 8:1, 7:1, 6:1, 5:1, 4:1, 3:1, 2:1, 1:1, 1:2, 1:3, 1:4, 1:5, 1:6, 1:7 or 1:8, although other ratios more than or less than the described ratios are within the contemplated scope of disclosure.

FIG. 4B is cross-sectional sectional view of a phase-change memory cell 100B that may be included in the PCRAM device 200 of FIG. 3, according to some embodiments of the present disclosure. The memory cell 100B is similar to the memory cell 100A, so only the differences therebetween will be discussed in detail.

Referring to FIG. 4B, the memory cell 100B omits the barrier electrode 144 and the selector layer 160 of the memory cell 100A. Accordingly, the top electrode 142 directly contacts the phase change layer 130 and the conductive line 658. In the embodiment memory cell 100B illustrated in FIG. 4B, the phase change layer 130 is a Ge-poor GST467 material, and the different variations and modifications of enlarged views (A) to (H) of FIG. 4B may refer to those described in FIG. 4A.

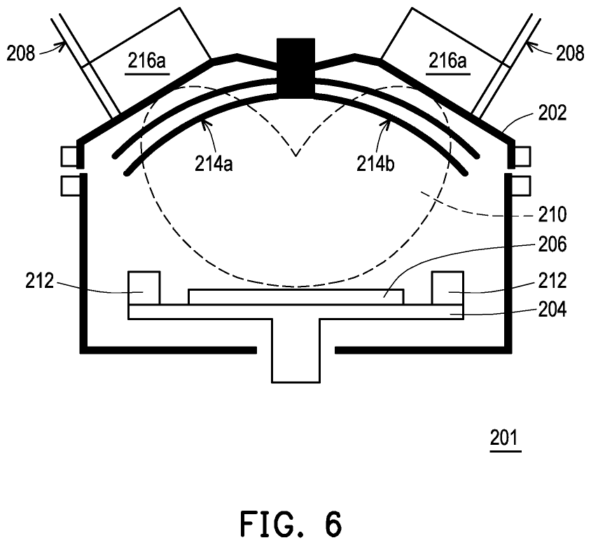

The phase change layer 130 may formed by a (PVD) process such as a sputtering process. In some embodiments, the sputtering process is illustrated with reference to the co-sputtering apparatus FIG. 6, although other suitable sputtering apparatuses are within the contemplated scope of disclosure.

FIG. 6 illustrates a co-sputtering apparatus 201 for forming a phase change layer according to some embodiments of the present disclosure. In some embodiments, the co-sputtering apparatus 201 includes a vacuum chamber 202 that surrounds a workpiece chuck 204 on which a semiconductor wafer or other semiconductor workpiece 206 is arranged. In some embodiments, the workpiece 206 is the intermediate stage of the memory device 200 at the stage for forming a memory layer such as a phase change layer 130. A gas delivery system 208, such as one or more pipes with valves, can deliver a sputtering gas and/or a dopant gas into the vacuum chamber 202 after a vacuum pump has pumped the vacuum chamber 202 down toward vacuum. After the vacuum chamber 202 has been pumped down towards vacuum and the sputtering gas has been flowed with a semiconductor workpiece 206 in place, a plasma 210 is ignited within the vacuum chamber 202. This plasma 210 is shaped or contained by one or more magnets 212 disposed around an edge of the workpiece chuck 204. First and second shutters 214a, 214b are opened to expose first and second sputtering targets 216a, 216b to the plasma 210, which concurrently ejects material from the first and second sputtering targets 216a, 216b so the ejected materials are deposited on the surface of the workpiece 206. The amount of ejection from the first and second sputtering targets 216a, 216b can be set by tuning a bias applied to each target, which controls the amount and/or velocity of electrons striking each target.

In some embodiments, the first sputtering target 216a is a Se₄Sb₆Te₇ target, and the second sputtering target 216b is a Sb₂Te₃ target. In some embodiments, each of the first and second sublayers 131 and 132 can be formed by a co-sputtering material from the first and second targets 216a, 216b; that is, both Se₄Sb₆Te₇ and Sb₂Te₃ compositions can be concurrently deposited on the exposed surface of the semiconductor workpiece 206. By tuning first and second biases applied to the first and second sputtering targets 216a, 216b, respectively, the relative proportions of Se₄Sb₆Te₇ and Sb₂Te₃ compositions can be tuned to desired Ge concentrations with desired thicknesses within the formed phase change layer.

In some embodiments, each of the first and second sublayers 131 and 132 can be formed by a sputtering material from one of the first and second targets 216a, 216b; that is, Se₄Sb₆Te₇ or Sb₂Te₃ composition can be deposited on the exposed surface of the semiconductor workpiece 206. By tuning on one of the first and second biases applied to the first and second sputtering targets 216a, 216b while turning off another of the first and second biases applied to the first and second sputtering targets 216a, 216b, one of Se₄Sb₆Te₇ and Sb₂Te₃ compositions can be tuned to desired thicknesses within the formed phase change layer.

In addition, because co-sputtering or sputtering can be carried out at relatively low temperatures compared to some other deposition techniques, the present disclosure can offer advantages from a thermal budget viewpoint, which is particularly desirable in BEOL processing.

Materials described herein can be doped with dopants or impurities to modify conductivity, transition temperature, melting temperature, and other properties of memory elements using the doped chalcogenides. Representative dopants or impurities used for doping chalcogenides include nitrogen, silicon, oxygen, silicon dioxide, silicon nitride, copper, silver, gold, aluminum, aluminum oxide, tantalum, tantalum oxide, tantalum nitride, titanium and titanium oxide. In some embodiments the phase change layer 130 includes a Ge-poor GST467 material that may be doped with a dopant such as N, Si, Sc, Ga, C, or any combination thereof. In some embodiments, the phase change layer 130 may include a Ge-poor GST467 material doped with about 1-10 at % of the dopant.

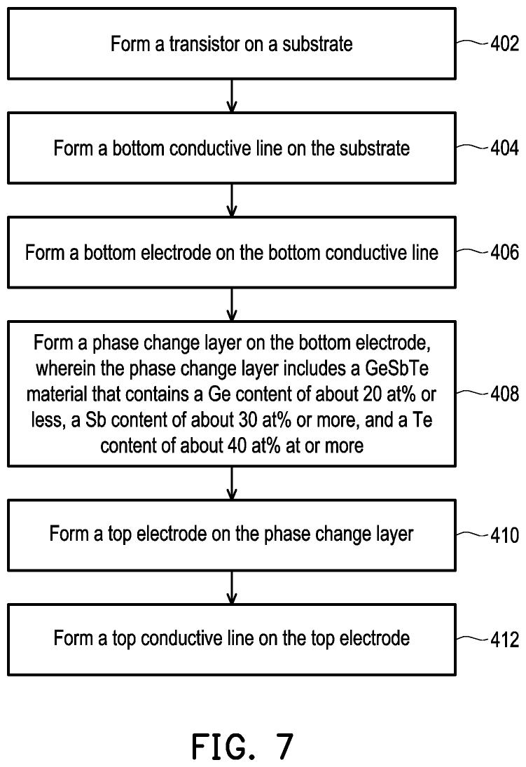

FIG. 7 is a flow chart showing a method of forming a memory device including a phase-change memory cell, according to some embodiments of the present disclosure. While the method is described with respect to forming a single memory cell, the method may include forming multiple memory cells, in some embodiments. Although the method is illustrated and/or described as a series of acts or events, it will be appreciated that the method is not limited to the illustrated ordering or acts. Thus, in some embodiments, the acts may be carried out in different orders than illustrated, and/or may be carried out concurrently. Further, in some embodiments, the illustrated acts or events may be subdivided into multiple acts or events, which may be carried out at separate times or concurrently with other acts or sub-acts. In some embodiments, some illustrated acts or events may be omitted, and other un-illustrated acts or events may be included.

Referring to FIG. 7, in act 402, the method may include forming at least one transistor on substrate. For example, a FET 700 may be formed on the substrate 30. Additional FET's 700 may also be formed on the substrate 30 for each memory cell 100 to be included in the memory device 200.

In act 404, metal interconnect features (612, 618, 622, 628, 632, 638, 642, 648, 658) may be formed on the substrate 30. Each of the metal interconnect features (612, 618, 622, 628, 632, 638, 642, 648) is separated by a dielectric layer (i.e., 601, 610, 620, 630, 640), with the conductive lines (e.g., 618, 628, 638, 648) of adjacent layers crossing one another in a mesh or grid pattern. The conductive lines (e.g., 618, 628, 638, 648) may include a bottom conductive line 648 of the memory cell.

In act 406, a bottom electrode 140 is formed on the bottom conductive line 648. In some embodiments, a bottom dielectric layer 650A may be formed on the bottom metal line 648. In act 406, a through-hole H1 may be formed in the bottom dielectric layer 650A using a patterned etching process. The through-hole H1 may expose the bottom conductive line 648 of the memory cell. Thereafter, the bottom electrode 140 of the memory cell 100 may be formed in the through-hole H1 using a deposition process and a planarization process.

In act 408, a phase change layer 130 is formed on the bottom electrode 140, wherein the phase change layer 130 includes a GeSbTe material that contains a Ge content of about 20 at % or less, a Sb content of about 30 at % or more, and a Te content of about 40 at % at or more. In some embodiments, the act of forming the phase change layer 130 includes co-sputtering from a Ge₄Sb₆Te₇ target and a Ge₂Te₃ target. In some embodiments, the act of forming the phase change layer 130 includes performing first sputtering processes and second sputtering processes alternately. In some embodiments, each first sputtering process includes co-sputtering from a Ge₄Sb₆Te₇ target and a Ge₂Te₃ target, and each second sputtering process includes sputtering the Ge₄Sb₆Te₇ target or the Ge₂Te₃ target. In some embodiments, the Ge content of the phase change layer 130 may be substantially constant. In other embodiments, the Ge content of the phase change layer 130 may be gradually varied.

In act 410, a top electrode 142 is formed on the phase change layer 130. In some embodiments, the act 408 and the act 410 are formed simultaneously. In some embodiments, the phase change layer 130 and the top electrode 142 may be formed by using deposition processes and followed by photolithography and etching processes.

In some embodiments, a barrier electrode 144 is optionally formed on the phase change layer 130 and a selector layer 160 is optionally formed on the barrier electrode 144 before the act 410. In such case, the layers 130, 144, 160, 142 may be formed by using deposition processes and followed by photolithography and etching processes. The middle dielectric layer 650B is formed to surround the phase change layer 130, the optional barrier layer 144, the optional selector layer 160, and the top electrode 142.

In act 412, a top conductive line 458 is formed on the top electrode 142. In some embodiments, a top dielectric layer 650C may be formed on the middle dielectric layer 650B. In act 410, a through-hole H2 may be formed in the top dielectric layer 650C using a patterned etching process. The through-hole H2 may expose the top electrode 142 of the memory cell. Thereafter, the top conductive line 458 of the memory cell 100 may be formed in the through-hole H2 using a deposition process and a planarization process.

In some embodiments of the disclosure, by providing a phase change layer with a Ge-poor GST467 material having a Ge content of less than about 20 at %, the phase change layer exhibits improved data retention characteristics and lower reset current. In addition, by providing the phase change layer with a dopant content of about 10 at % or less also provides for improved data retention, without degrading film quality during deposition.

According to an aspect of the present disclosure, a memory device structure is provided that includes a substrate, a bottom electrode disposed over the substrate, a top electrode disposed over the bottom electrode, and a phase change layer disposed between the top electrode and bottom electrode. The phase change layer includes a GeSbTe material that contains a Ge content of about 20 at % or less, a Sb content of about 30 at % or more, and a Te content of about 40 at % at or more.

According to an aspect of the present disclosure, a memory device includes: a lower interconnect structure over a substrate; a bottom electrode disposed over the lower interconnect structure; a top electrode disposed over the bottom electrode; a phase change layer disposed between the top electrode and bottom electrode, wherein the phase change layer includes Ge₄Sb₆Te₇ and Sb₂Te₃ in a ratio of 5:1 to 1:5; and an upper interconnect structure over the top electrode.

According to an aspect of the present disclosure, a method of forming a memory device includes: forming a transistor on a substrate; forming a bottom conductive line on the substrate; forming a bottom electrode on the bottom conductive line; forming a phase change layer on the bottom electrode; and forming a top electrode on the phase change layer, wherein the phase change layer includes a GeSbTe material that contains a Ge content of about 20 at % or less, a Sb content of about 30 at % or more, and a Te content of about 40 at % at or more.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory device, comprising:
a substrate;
a bottom electrode disposed over the substrate;
a top electrode disposed over the bottom electrode; and
a phase change layer disposed between the top electrode and bottom electrode, wherein the phase change layer comprises a GeSbTe material that contains a Ge content of about 20 at % or less, a Sb content of about 30 at % or more, and a Te content of about 40 at % at or more.

2. The memory device of claim 1, wherein the phase change layer comprises the Ge content of about 1-20 at %, the Sb content of about 30-55 at %, and the Te content of about 40-60 at %.

3. The memory device of claim 1, wherein the Ge content of the phase change layer is varied from about 5 at % to about 15 at % in a thickness direction extending between the bottom electrode and the top electrode.

4. The memory device of claim 3, wherein the Ge content of the phase change layer is continuously and gradually changed in a thickness direction extending between the bottom electrode and the top electrode.

5. The memory device of claim 3, wherein the Ge content of the phase change layer is discontinuously changed in a thickness direction extending between the bottom electrode and the top electrode.

6. The memory device of claim 1, wherein the Ge content of the phase change layer is substantially constant.

7. The memory device of claim 1, wherein the phase change layer comprises Ge₄Sb₆Te₇ and Sb₂Te₃ in a ratio of 10:1 to 1:10.

8. The memory device of claim 1, further comprising:
a barrier electrode disposed on the phase change layer; and
a selector layer disposed between the barrier electrode and the top electrode.

9. A memory device, comprising:
a lower interconnect structure over a substrate;
a bottom electrode disposed over the lower interconnect structure;
a top electrode disposed over the bottom electrode;
a phase change layer disposed between the top electrode and bottom electrode, wherein the phase change layer comprises Ge₄Sb₆Te₇ and Sb₂Te₃ in a ratio of 5:1 to 1:5; and
an upper interconnect structure over the top electrode.

10. The memory device of claim 9, wherein the Ge content of the phase change layer is varied changed in a thickness direction extending between the bottom electrode and the top electrode.

11. The memory device of claim 9, wherein the Ge content of the phase change layer is substantially constant.

12. The memory device of claim 9, wherein the phase change layer comprises first sublayers and second sublayers alternately stacked.

13. The memory device of claim 12, wherein the first sublayers and the second comprise different materials.

14. The memory device of claim 12, wherein each of the first sublayers and the second comprises Se₄Sb₆Te₇, Sb₂Te₃ or a combination thereof.

15. The memory device of claim 9, wherein the phase change layer comprises a Ge content of about 20 at % or less.

16. The memory device of claim 15, wherein the phase change layer further comprises a Te content of about 30 at % or more and a Sb content of about 40 at % or more.

17. A method of forming a memory device, comprising:
forming a transistor on a substrate;
forming a bottom conductive line on the substrate;
forming a bottom electrode on the bottom conductive line;
forming a phase change layer on the bottom electrode; and
forming a top electrode on the phase change layer, wherein the phase change layer comprises a GeSbTe material that contains a Ge content of about 20 at % or less, a Sb content of about 30 at % or more, and a Te content of about 40 at % at or more.

18. The method of claim 17, wherein forming a phase change layer comprises co-sputtering from a Ge₄Sb₆Te₇ target and a Ge₂Te₃ target.

19. The method of claim 17, wherein forming a phase change layer comprises performing first sputtering processes and second sputtering processes alternately.

20. The method of claim 19, wherein the first sputtering process comprises co-sputtering from a Ge₄Sb₆Te₇ target and a Ge₂Te₃ target, and the second sputtering process comprises sputtering the Ge₄Sb₆Te₇ target or the Ge₂Te₃ target.
